(19) United States
(12) Patent Application Publication
(10) Pub. No.: US 2011/0209849 A1
(43) Pub. Date: Sep. 1, 2011

(54) ARRANGEMENT AND METHOD FOR UTILIZING THE HEAT BUILT UP ON PHOTOVOLTAIC SYSTEMS OF DOMESTIC INSTALLATIONS

(76) Inventors: Heiko Reichert, Halle (DE); Maik Richter, Walldurn (DE)

(21) Appl. No.: 13/125,546

(22) PCT Filed: Sep. 25, 2009
(86) PCT No.: PCT/EP09/62461

§ 371 Date: Apr. 21, 2011

(30) Foreign Application Priority Data
Oct. 31, 2008 (DE) 10 2008 054 099.4

(51) Int. Cl. F24H 3/04; H01L 31/052

(52) U.S. Cl. 165/47; 136/246; 165/104.34

(57) ABSTRACT

The invention relates to a technical embodiment and a method for utilizing air in conjunction with heat pumps and other domestic installations or the house as such, e.g. basements, staircases etc., said air being heated up on photovoltaic systems. The aim of the invention is to devise a technical embodiment with an improved dimensional shape and a method for utilizing air in conjunction with heat pumps and other domestic installations or the house as such, e.g. basements, staircases etc., said air being heated up on photovoltaic systems. The photovoltaic modules comprise modular mounting rails that extend from the gutter to the rooftop and are arranged on the sloped surface/roofing in such a manner that the channels formed in this manner and generating a current or draft of air have lamellar cages on the lower inlet and ventilators on the upper outlet. The ventilators are incorporated into a collecting channel having individual ducts and being arranged at the upper outlets so as to interconnect them crosswise, said channel being connected to a multiport air mixer lying under the sloped surface/roofing via an additional air channel which supplies air to an air/water heat pump. In another embodiment, the system is used for tilting mounts in open space installations.

The invention relates to an engineering embodiment of the three dimensional shape and method for utilizing the air being heated at photovoltaic systems in conjunction with heat pumps and other building systems.

It is well-known with respect to the passive and plus energy constructions of buildings that, among other things, the energy is recovered from the environment of the constructions concerned and delivered to the building systems. It is also common knowledge that in order to recover energy from solar energy, preferably solar collectors are used for the direct recovery of heat and that preferably photovoltaic systems are used for the recovery of electric energy from the incident light rays/solar rays. In addition, it is also known from the prior art that industrial development has created combination arrangements of solar collectors and photovoltaic systems. To this end see DE 20 2007 009 162 U1. Although this document states with respect to the solar collector modules “for absorbing the solar recoveries,” it does not state why such a combination was created and what advantageous purpose it is supposed to serve, since the solar collector modules are disposed on the underside of the photovoltaic modules—that is, the side (shaded side) facing away from the solar rays—in fact, even in the light attenuated area between the photovoltaic modules and the roof surface. At best one can guess the advantageous effect to be produced by this type of arrangement. It is known that when photovoltaic modules are used, they heat up and, in particular, that warm air forms underneath. In order to prevent the efficiency of these photovoltaic modules from degrading as they heat up, it is necessary to cool them. A solution for this problem is offered by the document EP 1 806 706 A1 by disclosing a composite body as a substitute for conventional roof covering elements (roof tiles), comprising photovoltaic elements and roof covering and/or wall covering elements made of glass fiber-reinforced plastic (GFRP) with integrated water cooling in the form of laminated copper pipes (acting additionally also as a carrier). The result is an autonomous roof covering element comprising photovoltaic and single thermosolar elements. The thermal energy that is recovered in this way is delivered, according to this engineering solution, to a buffer storage and serves, moreover, to provide hot water. Therefore, according to the prevalent literature, there has been no solution to date for the problem of protecting the conventional photovoltaic modules—that is, commercial parts—that do not represent custom-made designs from overheating, and thus protecting them from a decrease in their efficiency, and in particular the problem of utilizing the excess (waste) heat that is generated at said photovoltaic modules.

Working on the basis of this prior art and its drawbacks, the object of the invention is to protect the efficiency of the photovoltaic modules from decreasing when they are put into operation, and to feed the hot air that is generated when the photovoltaic modules are put into operation to its energetic use at and in buildings, in particular residential buildings.

The invention solves this problem and engineering object with the characterizing parts of claims 1 and 8. Additional advantageous engineering solutions are apparent from the claims 2 to 7 and 9 to 12. The advantageous effects of this inventive engineering solution in its three-dimensional shape are apparent especially from the fact that an engineering solution is offered that actually results in a cooling of the photovoltaic modules and in an energetic utilization of this cooling air, which has absorbed the thermal energy, in those sections of building systems that are a part of residential buildings. According to the invention, the photovoltaic modules are mounted by means of modular mounting rails, which extend from the roof gutter to the roof gable, on the top side of the sloped surface or, more specifically, the roof membrane. Said modular mounting rails form a continuous spaced channel without their own openings and are arranged in a row so as to be interconnected. As an alternative to the smooth, sloped surface or roof membrane, it is possible to apply mats or boards planarly in a form-locking or force-locking manner on the roof membrane or rather the sloped surface, as they also exist in the case of the hereinafter referred to and described raised systems. These mats or boards are structured—for example, pebbled—on one side in the direction of the photovoltaic module and are made of a material that is a poor heat conductor, preferably plastic mats, because these usually exhibit poor thermal conductivity. The advantageous result is air turbulence or rather an eddy current, instead of the laminar flows that usually prevail, and, hence this turbulence absorbs more heat. Moreover, the undesired heat transfer from the hot air to the roof membrane, and thus the entire roof body, is prevented or rather decreased. The channels, which are formed as described above and which generate an upward air current or air draft, have squirrel cage fans on the lower input and ventilators, which also comprise squirrel cage fans, on the upper output. In the case of the elevated photovoltaic systems—for example, large open space installations—there shall be a final extensive box, which is made of a material that is a poor heat conductor, and is disposed on the underside or rear side of the photovoltaic modular arrangement, in order to replace the missing roof membrane and the resulting space—the channels generating the aforesaid upward air current or air draft—and additionally to bring about an ordered or rather forced transport of the heat generated at and under the photovoltaic modules. In this case, too, the lower input has squirrel cage fans and the upper output has ventilators, which are also provided with squirrel cage fans. These aforesaid ventilators in turn are integrated into a collecting channel, which exhibits individual shafts and is arranged in a transversely connecting manner at the upper outputs. These squirrel cage fans are provided individually per upwards extending channel, or rather per shaft in the collecting channel, and each of these cages can be controlled individually. The collecting channel consists of integrated single shafts, each of which is provided with a squirrel cage fan, and is connected to a multiport air mixer, which is located under the sloped surface or more specifically the roof membrane, by means of an additional air channel. This additional connecting air channel is provided with an integrated suction/pressure ventilator, which can be switched over in order to mix the air, and empties into a multiport mixer, which is provided for the purpose of passing the air to an air/water heat pump or into the ventilation system of the building/house or into the building body itself—for example, the basement, stairwells etc. The flowing outside air that changes its temperature due to the heat exchange enters at the lower end exhibiting the squirrel cage fan, flows through the channel that generates the upward air current or air draft, then under the photovoltaic module and enters in a heated state at the upper output exhibiting the ventilator into the collecting channel with its controllable squirrel cage fan, in order to be distributed among the individual shafts inside the collecting channel. The heated air is delivered to a multiport air mixer by way of the connecting air channel provided with an integrated suction/pressure ventilator.

At the lower edge of the photovoltaic modules, the outside air enters through the squirrel cage fans into the channels below the photovoltaic modules and the resulting heated air flows between them and the upper side of the sloped surface or more specifically the roof membrane into the channels provided with the controllable squirrel cage fans, which are also disposed at the top of said channels, to the roof ridge upper edge or rather the upper edge of the sloped surface. There at the top, the heated air is drawn off over the individual shafts by means of the collecting channel, located there, through the suction ports, which are located in said channel and which are provided with controllable squirrel cage fans, and the ventilator, which may be disposed there. Then said air is passed by means of an additional air channel having an integrated suction/pressure ventilator into the multiport air mixer for the purpose of being delivered to an air/water heat pump or into the building/house ventilation system or the building body itself—for example, the basement, the stairwell, etc. The aforesaid individual shafts of the collecting channel may be connected or disconnected as necessary, by means of the individually controllable squirrel cage fans. The air in the multiport air mixer is conditioned in such a way that the hot air is mixed, as a function of the requirements, with fresh intake air and/or cold blow-off air of the heat pump. In the winter, as needed, the air flow in the connecting air channel with the integrated suction/air ventilator can be reversed and, as a result, the photovoltaic modules can be heated for the purpose of melting the snow/ice covering the photovoltaic modules.

The invention in its three-dimensional shape is explained below by means of the following embodiment.

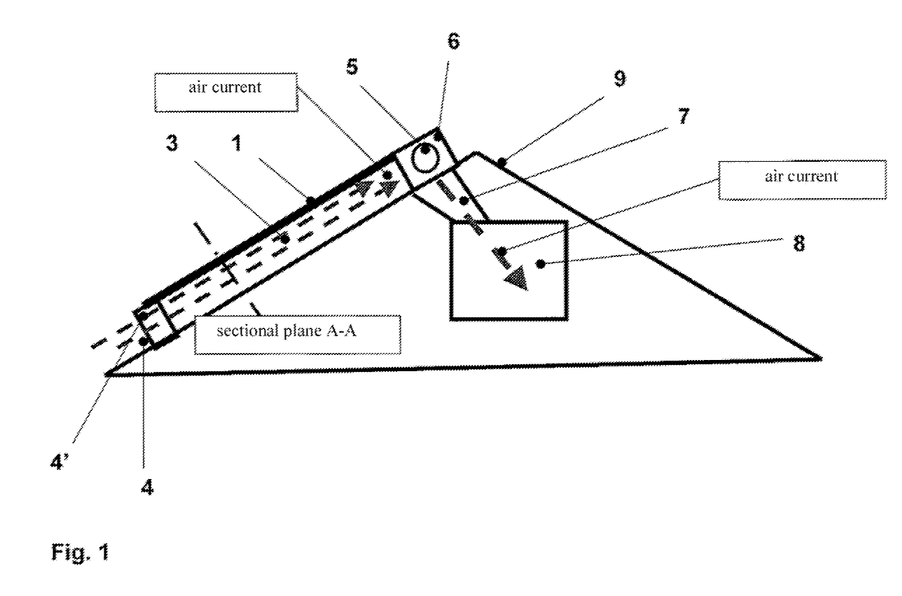

FIGS. 1 to 6 represent parts of the essentials for the invention.

FIG. 1 shows the spatial arrangement of the arrangement elements up to the multiport air mixer

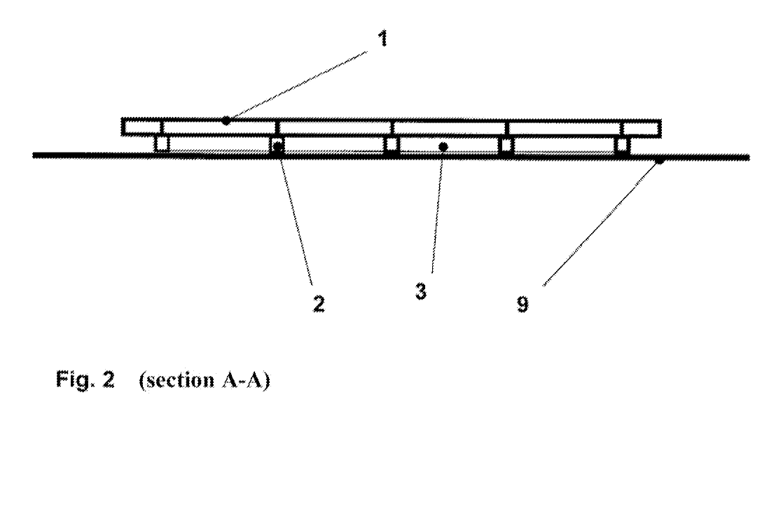

FIG. 2 shows the arrangement of the photovoltaic modules on a sloped surface or more specifically a roof

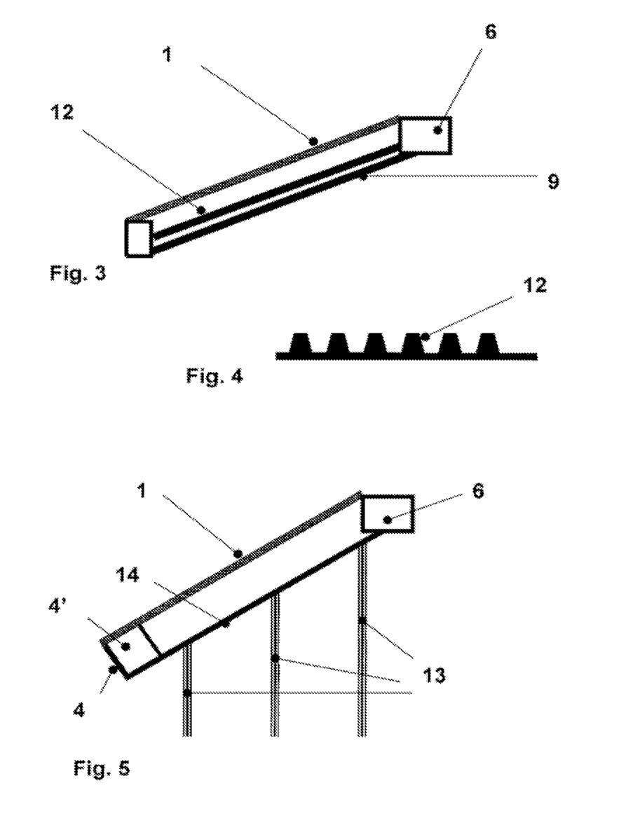

FIG. 3 shows the spatial arrangement of a structured mat or board, made of a material that is a poor heat conductor, on the roof membrane or rather a sloped surface, thus in the channel

FIG. 4 shows the structured mat or board in a side view

FIG. 5 is a side view of an elevated arrangement

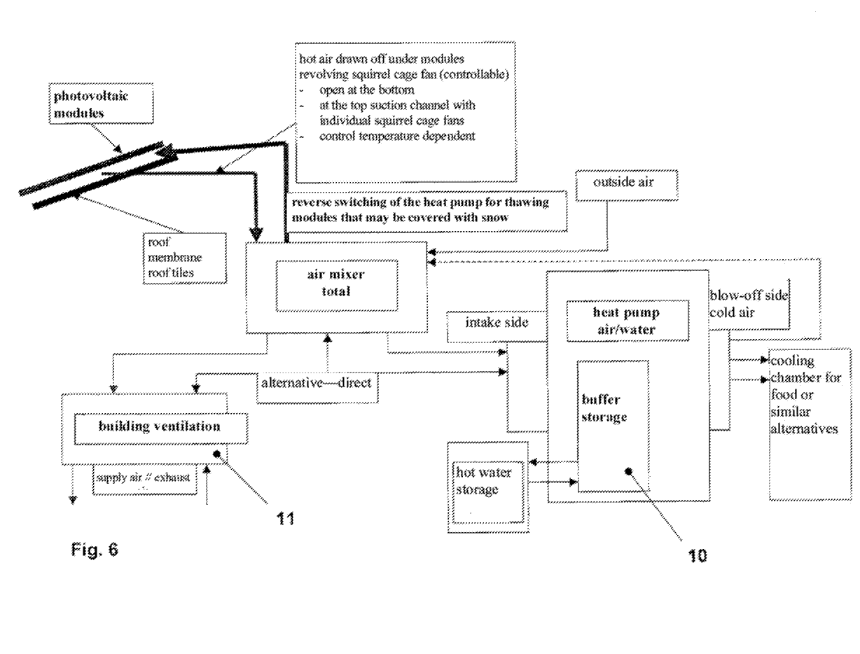

FIG. 6 shows the whole arrangement of a conceivable building system

### EXEMPLARY EMBODIMENT 1

One possible example of the invention is described below as follows.

The photovoltaic modules 1 are mounted by means of modular mounting rails 2, which extend from the roof gutter to the roof gable, on the top side of the sloped surface/roof membrane 9. Said modular mounting rails form a continuous spaced channel without their own openings and are arranged in a row so as to be interconnected. The channels 3, which are formed in this way and generate an upward air current or air draft, have squirrel cage fans 4′ on the lower input 4 and ventilators 5 on the upper output. A pebbled board 12 made of a synthetic plastic material is applied in a planar manner on the roof membrane 9. This plastic board swirls the upward flowing air and prevents or at least reduces the undesired transfer of heat from the hot air to the roof membrane, and thus to the whole roof body. The ventilators 5 in turn are integrated into a collecting channel 6, which is arranged in a transversely connecting manner to the upper outputs and which consists of integrated individual shafts, each of which is provided with a squirrel cage fan. The squirrel cage fans 4′, which are provided individually per upwards extending channel (3) or more specifically per shaft in the collecting channel 6, are provided so that each one can be controlled individually by itself. This collecting channel 6 is connected to a multiport air mixer 8, which is located under the sloped surface/roof membrane 9, by way of an additional air channel 7, which is provided with an integrated suction/pressure ventilator that can be switched over, for the purpose of mixing the air. The hot air that is generated under the photovoltaic modules 1 is passed between them and the upper side of the sloped surface or more specifically the roof membrane 9 in the channels 3 comprising the controllable squirrel cage fans 4′, which are disposed at the bottom or top of said channels, to the roof ridge upper edge or rather the upper edge of the sloped surface 9. There at the top, the air is drawn off over the individual shafts by means of the collecting channel 6, located at said top, and through the suction ports, which are located in said channel and which are provided with controllable squirrel cage fans 4′, and the ventilator 5, which may be disposed there. Then said air is passed by means of an additional air channel 7 having an integrated suction/pressure ventilator into the multiport air mixer 8 for the purpose of being delivered to an air/water heat pump 10 or into the building/house ventilation system 11 or the building body itself—for example, into the basement and the stairwell. The individual shafts of the collecting channel 6 may be connected or disconnected as necessary by means of the individually controllable squirrel cage fans 4′. The air in the multiport air mixer 8 is delivered to an air/water heat pump 10 and/or a building/house ventilation system 11 or the building body itself, such as the basement and the stairwell. The air in the multiport air mixer 8 is conditioned in such a way that the hot air is mixed, as a function of the requirements, with fresh intake air and/or cold blow-off air of the heat pump 10. In the winter, as needed, the air flow in the connecting air channel 7 with the integrated suction/air ventilator can be reversed, thus heating up the photovoltaic modules 1 for the purpose of melting the snow/ice covering the photovoltaic modules 1.

### EXEMPLARY EMBODIMENT 2

The whole spatial arrangement is not on a roof or any other type of sloped surface, but rather is set up independently and autonomously on stands 13 as a large open space system—for example, a closed and covered landfill. Since the sloped surface—for example, a roof membrane—is not available, a box 14 is constructed on stands 13 which supports in an integrating manner the photovoltaic modules and the other arrangement elements according to the embodiment 1. This box configuration, into which the pebbled boards can be laid, guarantees the operating principle of the channel flow with the air swirling by means of the nubs.

1. Arrangement for utilizing the heat generated at photovoltaic systems inside building systems, wherein the commercially available photovoltaic modules are used on sloped surfaces, in particular on roofs,
wherein these photovoltaic modules (1) are mounted by means of modular mounting rails (2), which extend from the roof gutter to the roof gable, on the top side of the sloped surface/roof membrane (9), said modular mounting rails forming a continuous spaced channel without their own openings and being arranged in a row so as to be optionally interconnected,
are arranged on the sloped surface/roof membrane (9),
that the sloped surface/roof membrane (9) has inside the formed channels (3) planar flat elements, which are structured with definite elevations in the direction of the photovoltaic module (1) and which are made of a material (12) that is a good heat insulator,
that the channels (3), which are formed in this way and generate an upward air current or air draft, have squirrel cage fans (4′) on the lower input (4) and ventilators (5) on the upper output,
that the ventilators (5) in turn are integrated into a collecting channel, which is arranged in a transversely connecting manner to the upper outputs and which comprises individual shafts (6).
that the collecting channel (6) is connected to a multiport air mixer (8), which is located under the sloped surface/roof membrane (9), by way of an additional air channel (7).

2. Arrangement, as claimed in claim 1,
wherein the sloped surfaces are formed by a stand assembly by means of stands (13) and that in order to form the channel of these stands one or more all-encompassing boxes (14) are mounted on these stands, said boxes containing the photovoltaic modules (1) and the other arrangement elements (2) to (8).

3. Arrangement, as claimed in claim 1,
wherein the flat surfaces, structured with definite elevations, are made of a synthetic plastic material in mat, board or other form with a very high thermal insulating capacity.

4. Arrangement, as claimed in claim 1,
wherein the squirrel cage fans (4′) are provided individually per upwards extending channel (3) or more specifically per shaft in the collecting channel (6); and each of these cages can be controlled individually.

5. Arrangement, as claimed in claim 1,
wherein the collecting channel (6) consists of integrated single shafts, each of which is provided with a squirrel cage fan.

6. Arrangement, as claimed in claim 1,
wherein the additional connecting air channel (7) is provided with an integrated suction/pressure ventilator that can be switched over, in order to mix the air.

7. Arrangement, as claimed in claim 1,
wherein the flowing air, which changes its temperature due to the heat exchange, in the arrangement and spatial parts: the lower input (4) with
squirrel cage fan (4′),
channel (3), which generates the upward air current or air draft,
upper output with ventilator (5),
collecting channel (6) with controllable squirrel cage fan and individual shafts,
connecting air channel (7) with integrated suction/pressure ventilator
and
multiport air mixer (8)—is provided for the purpose of being delivered to an air/water heat pump or into the building/house ventilation system or the building body itself—for example, into the basement and/or into the stairwell.

8. Method for utilizing the heat generated at photovoltaic systems inside building systems, wherein the commercially available photovoltaic modules are used on sloped surfaces, in particular on roofs,
wherein the hot air that is generated under the photovoltaic modules (1) is passed between them and the upper side of the sloped surface or more specifically the roof membrane (9) in channels (3) comprising the controllable squirrel cage fans (4′), which are disposed at the bottom or top of said channels, to the roof ridge upper edge or rather the upper edge of the sloped surface (9), so that the structured elements (12) swirl this air which, as a result, on the one hand cools the photovoltaic modules (1) and, on the other hand, absorbs their thermal energy for energetic utilization,
that there at the top the air is drawn off over the individual shafts by means of the collecting channel (6), located at said top, through the suction ports, which are located in said channel and which are provided with controllable squirrel cage fans (4′), and the ventilator (5), which may be disposed there, and that then said air is passed by means of an additional air channel (7) having an integrated suction/pressure ventilator into the multiport air mixer (8) for the purpose of being delivered to an air/water heat pump (10) or into the building/house ventilation system (11) or the building body itself—for example, the basement and the stairwell.

9. Method, as claimed in claim 6,
wherein the individual shafts of the collecting channel (6) are connected or disconnected as necessary by means of the individually controllable squirrel cage fans (4′).

10. Method, as claimed in claim 6,
wherein the air conditioned in the multiport air mixer (8) is delivered to an air/water heat pump (10) and/or a building/house ventilation system (11) or the building body itself—for example, the basement and stairwell.

11. Method, as claimed in claim 8,
wherein the air in the multiport air mixer (8) is conditioned in such a way that the hot air is mixed, as a function of the requirements, with fresh intake air and/or cold blow-off air of the heat pump (10).

12. Method, as claimed in claim 6,
wherein in the winter, as needed, the air flow in the connecting air channel (7) with the integrated suction/air ventilator is reversed, thus heating up the photovoltaic modules (1) for the purpose of melting the snow/ice covering the photovoltaic modules (1).
